(19) United States
(12) Patent Application Publication
(10) Pub. No.: US 2005/0193314 A1
(43) Pub. Date: Sep. 1, 2005

(54) Method of correcting an erroneous frame by a receiver

(75) Inventors: Catherine Lamy, Paris (FR); Sandrine Merigeault, Paris (FR)

Correspondence Address: PHILIPS INTELLECTUAL PROPERTY & STANDARDS, P.O. BOX 3001, BRIARCLIFF MANOR, NY, 10510, US

(73) Assignee: KONINKIJKE PHILLIPS ELECTRONICS N.V.

(21) Appl. No.: 10/515,692

(22) PCT Filed: May 19, 2003
(86) PCT No.: PCT/IB03/02136

§ 371 Date: Nov. 24, 2004

(30) Foreign Application Priority Data
May 28, 2002 (FR) 0206501

(51) Int. Cl. H04J 15/00; H03M 13/00

(52) U.S. Cl. 714/758

(57) ABSTRACT

The present invention relates to a method of processing a received data unit (UDR) by a receiver via a network, the method comprising a channel decoding stage (CDEC1, CDEC2) of the received data unit (UDR), intended to deliver a hard bit string (TBD), a transformation stage for transforming said hard bit string into a hard frame (TD), said hard frame comprising at least an error detector code and a test stage (TST) intended to test with said error correcting code if said hard frame (TD) is correct or incorrect. Said method is characterized in that it further comprises a frame correction stage (COR) intended to correct an incorrect frame (TE) into a correct frame (TCo). In the preferred embodiment of the invention said frame correction stage (COR) utilizes soft data delivered by a soft output channel decoding stage (CDEC2). The advantage of such a method is that rejects and retransmissions of frames are avoided.

The present invention relates to a processing method for a data unit received by a receiver, the method comprising a channel decoding stage of the received data unit, intended to deliver at least a string of hard bits, a transformation stage of said hard bit string into a hard frame, said hard frame comprising at least an error detecting code and a test stage intended to test on the basis of said error detecting code if said hard frame is correct or incorrect.

The invention also relates to a receiver comprising means for implementing such a method.

The invention also relates to a transmission system comprising such a receiver.

The invention also relates to a computer program which implements such a method when it is executed by a processor.

The invention finally relates to a signal conveying such a program.

The invention notably finds its application in data transmission via a network having high error rates, for example, a wireless network.

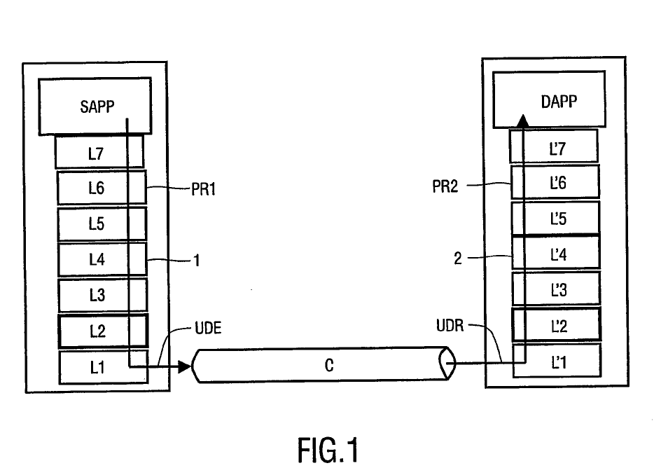

The transmission of digital data between a source application and a destination application is generally effected by means of a network as is shown in FIG. 1. Such a network is organized in layers, for example, according to the OSI reference model (Open Systems Interconnection), comprising seven layers. These layers are managed by protocols and form a stack called network stack.

When a source application SAPP sends data to a destination application DAPP via a network, said data are to pass through a first network stack PR₁ from top to bottom before reaching the transmission channel C and being transmitted in the form of a unit of transmitted data UDE. This first stack and the source application SAPP are considered to belong to a transmitter 1. A data unit UDR is then received by a second network stack PR₂ which it is to pass through from bottom to top before being given access to the destination application DAPP. The second stack and the destination application are considered to form part of a receiver 2.

At the transmitter end as well as the receiver end the layers of a network stack each ensure well-defined functions. In that which follows a distinction will be made between the layers (L₁, L₂, . . . , L₇) of the network stack PR₁ situated at the transmitter end (L′₁, L′₂, . . . , L′₇) from those of the network stack PR₂ situated at the receiver end.

Let us consider in particular the two first layers called base layers, that is to say:
the physical layer L₁ (L′₁ respectively) which provides the transmission of hard data over the transmission channel C. It generally comprises a channel coder (decoder respectively) charged with coding (decoding respectively) the data so as to protect them from possible disturbance during transmission;
the data link layer L₂ (L′₂ respectively) whose main aim is to transmit the data of the network layer L₃ from a transmitter to the network layer L′₃ of a receiver. On the side of the transmitter, the data link layer L₂ converts a frame transmitted via the network layer L₃ into a bit string which it directs to the physical layer L₁. On the side of the receiver, the data link layer L′₂ divides the received bit string into data frames that have almost no errors.

To transmit the data from the network layer L₃ of a transmitter to the network layer L′₃ of a receiver, the data link layer is thus to make use of the service of the physical layer L₁ (L′₁ respectively). The latter ensures the transport of data units over the transmission channel C and their return to the network stack PR₂. On the side of the transmitter, the physical layer L₁ comprises a channel coder which converts a bit string into a data unit UDE. The data unit UDE is sent over the transmission channel C. On the side of the receiver a received data unit UDR is converted into a received bit string by a channel decoder.

Such a bit string may have errors. Such errors have various causes, for example, an attenuation of the signal transmitted over the transmission channel, or noise or also a congestion of the network. The number of received bits may be lower than or equal to or higher than the number of transmitted bits. The value of certain bits may also have changed. In order to be able to detect possible transmission errors at the receiver end, the data link layer L₂ at the transmitter end generally adds error-detecting codes to the data it receives from the network layer L₃. From these codes, from received data and from other control codes it constructs at least one frame. With the aid of these error detecting codes it calculates, for example, a checksum for each frame. When a frame arrives at its destination, the data link layer L′₂ at the receiver end recalculates this checksum. If the result obtained is different from that calculated by the transmitter, the data link layer knows that a transmission error has occurred. It may then take measures such as rejecting the received frame and sending a negative settlement to the transmitter. In that case the transmitter will be able to retransmit the frame, for example. However, it happens that only several bits of the received frame are corrupted. In that case the fact that the retransmission of said frame is requested is particularly costly in terms of overloading the network and processing time and this in relation to the low number of erroneous bits.

On the other hand, if the result is identical, the data link layer at the receiver end takes the received frame into account and may send a positive acquittal to the transmitter.

It should be noted that very often the physical layer L₁ itself adds error correcting codes to a data unit before sending it over the transmission channel C. Such correcting codes are used on the side of the receiver by the physical layer L′₁ to detect and correct transmission errors. Contrary to the error detecting codes which decide with a very low error margin if a frame is correct or incorrect, the error correcting codes correct a data unit so as to produce therefrom a version corrected in the best possible way as regards said codes. The corrected data unit is then offered to the channel decoder which delivers a bit string.

It should finally be noted that for reasons of transmission costs the data link layer L₂ or L′₂ almost never utilizes error correcting codes except in the particular case of a one-way channel, thus does not permit the retransmission of an erroneous frame.

These detecting codes and error correctors are described in the third edition (ISBN 2 10004315 3) of the book entitled “Networks” written by Andrew Tanenbaum, edited by Dunod in the collection “Prentice Hall”, particularly pages 192 to 198.

It is an object of the present invention to propose a solution for correcting an erroneous frame, the solution comprising at least an error detecting code at the data link layer of the receiver so as to avoid the transmitter retransmitting said erroneous frame.

This object is achieved by the method as described in the opening paragraph and characterized in that it comprises a frame correction stage intended to correct an incorrect frame into a correct frame, said stage comprising:
a sub-stage of selecting bits to be corrected in an incorrect frame, from data extrinsic to said incorrect frame,
a sub-stage of generating a candidate frame from bits to be corrected and from the incorrect frame, said candidate frame being intended to be tested by the test stage.

An advantage of the method according to the invention is that the number of retransmissions of erroneous frames is limited and thus the network is not uselessly crowded.

The selection sub-stage for bits to be corrected selects in the erroneous frame the bits of which the probability of being erroneous is largest. Such a selection is made, for example, from data which are present at the receiver end, which are for example a priori knowledge of the coding technique of the data on the side of the transmitter or from data generated by the receiver from the received data unit.

The candidate frame generation sub-stage generates a candidate frame by modifying bit values to be corrected.

The candidate frame obtained is then tested by the test stage. If said stage declares the candidate frame to be correct, the candidate frame replaces the erroneous frame by the candidate frame that is sent to the upper layer of the network stack, that is to say, the network layer.

In a first embodiment of the invention said frame correction stage is repeated as long as the candidate frame generation stage delivers a new candidate frame and as long as the new candidate frame is declared to be erroneous by said test stage. An advantage of this embodiment is that it permits to test various candidate frames, which increases the chances of correcting the erroneous frame. On the other hand, it is necessary to provide an end for said repetitions in order to avoid blocking the processing of data units received by the receiver. In other words, this is about establishing a compromise between retransmission of erroneous frames and processing time by the receiver.

It is for this reason that in a second embodiment of the invention the frame correction stage further includes a check sub-stage intended to count a number of candidate frames and to stop the generation and the test of candidate frames if said number reaches a predetermined threshold. An advantage of this second embodiment is that the number of repetitions of the correction stage for erroneous frames is limited. If, after a certain number of attempts, no candidate frame has been declared correct by the test stage, the erroneous frame is rejected and the retransmission may be requested.

In a preferred embodiment of the invention the method comprises a channel decoding stage of the received data unit, intended to deliver a hard bit string and a soft bit string and a transformation stage for transforming said hard bit string into a hard frame and said soft bit string into at least one soft frame, said soft frames forming the extrinsic data of the hard frame. Said soft frames produce in effect for a given bit of the erroneous hard frame probability that this bit is exact. Such a probability is advantageously used during the sub-stage of selecting bits to be corrected.

The invention also relates to a receiver implementing the method according to the invention.

These and other aspects of the invention are apparent from and will be elucidated, by way of non-limitative example, with reference to the embodiment(s) described hereinafter and to the accompanying drawings in which:

FIG. 1 describes a transmission system for transmitting data via a network;

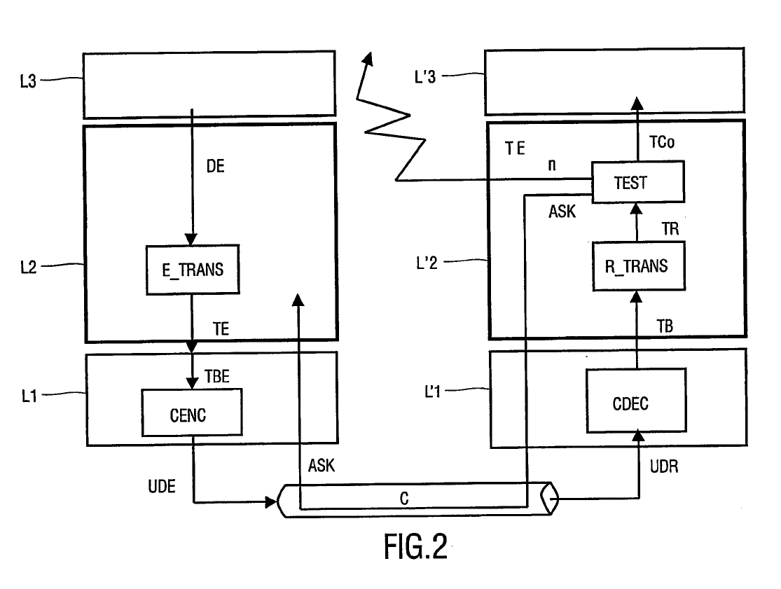

FIG. 2 is a block diagram of the data link layer of a network stack according to the prior art;

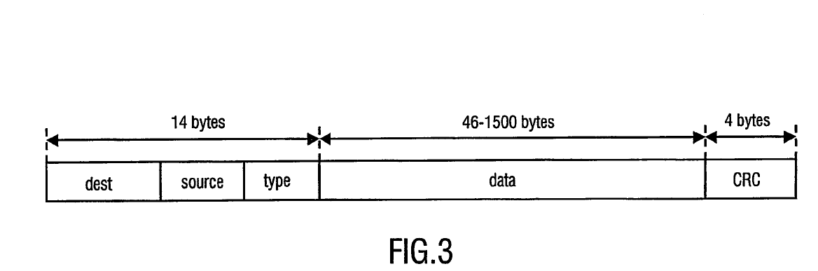

FIG. 3 is an example of a frame delivered by the sub-layer MAC of the data link layer in the case of the Ethernet standard;

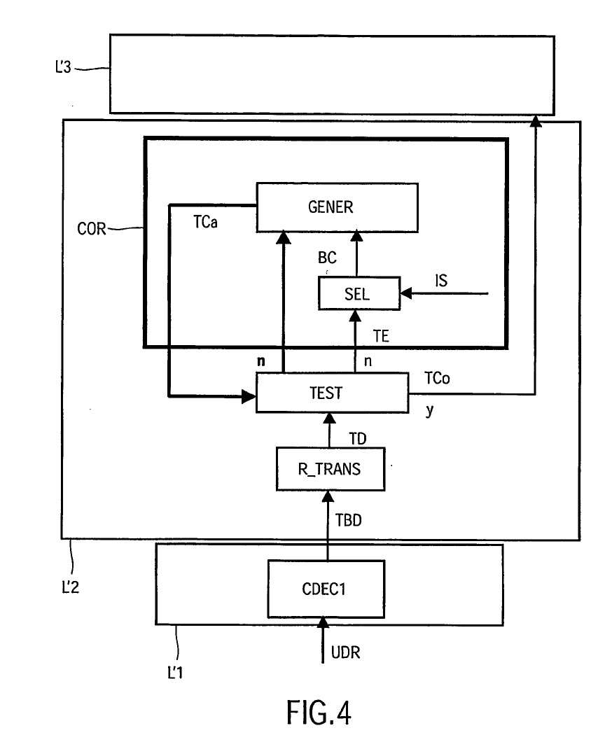

FIG. 4 is a block diagram of the correction method of an erroneous frame according to the invention;

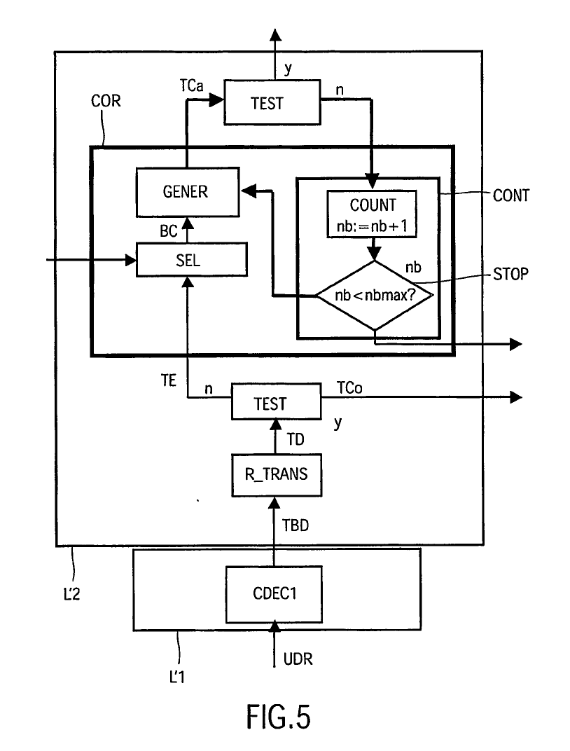

FIG. 5 is a block diagram of the method according to the invention comprising a stage of controlling the number of generated candidate frames;

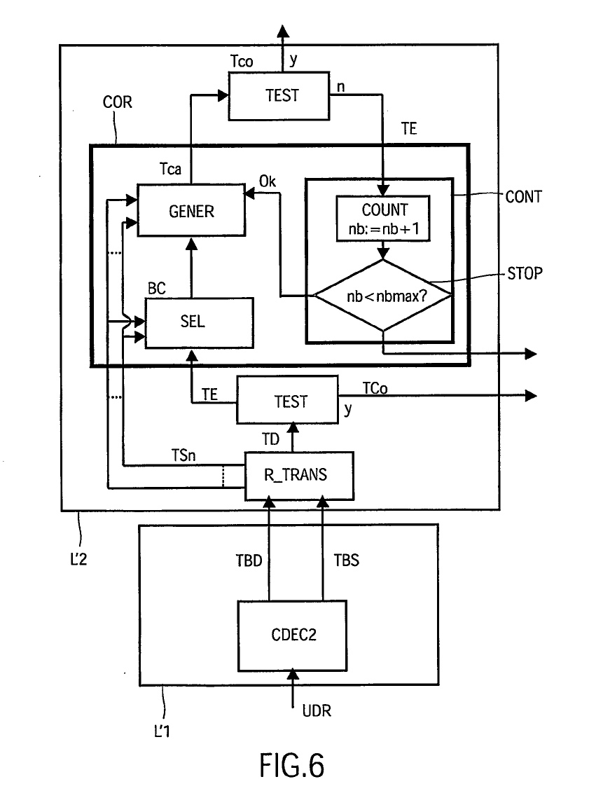

FIG. 6 is a block diagram of the method according to the invention comprising a soft output channel decoding stage and a stage of checking the number of generated candidate frames; and

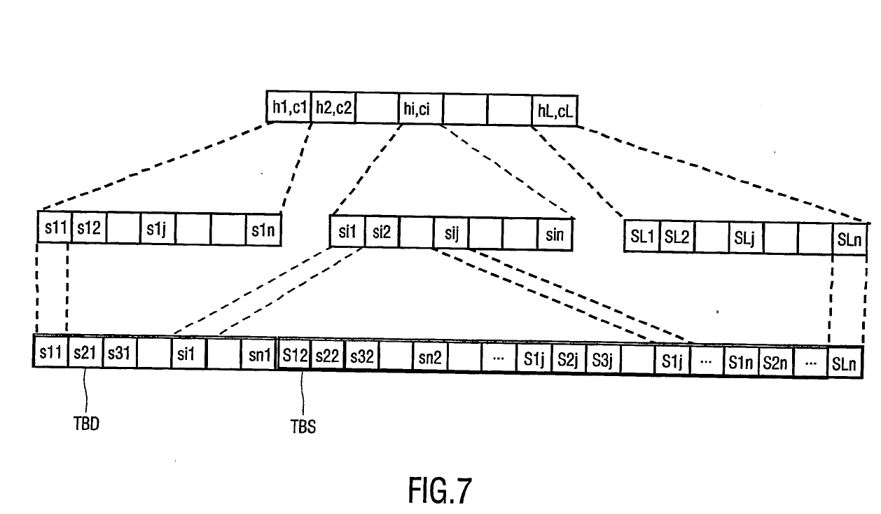

FIG. 7 describes hard bit string and soft bit string structures produced by the channel decoding stage.

FIG. 2 shows the data link layer L₂ of a network stack. On the side of the transmitter, such a layer comprises a transformation stage E_TRANS of transmitted data DE via the network layer L₃ into a transmitted frame TE. This transformation stage E_TRANS consists of adding check codes to the data DE. The transmitted frame TE is converted into a bit string TBE, then coded by the channel encoder CENC which delivers a unit UDE of transmitted data. On the side of the receiver, a received data unit UDR is decoded by a channel decoder CDEC which delivers a received bit string TB. A symmetrical transformation stage R_TRANS then consists of finding back at least one frame called received frame TR in said received bit string TB. Let us consider the particular case of a local area network or LAN utilizing the Ethernet standard (or IEEE 802.3). Such a network comprises a transmission channel, also called broadcast channel, which is bi-directional. In this context the data link layer L₂ or L′₂ comprises a sub-layer of channel access control which is called MAC sub-layer (Medium Access Control) and is notably in charge of managing the potential user access to the transmission channel C. Said sub-layer also comprises the transformation stage R_TRANS mentioned previously. FIG. 3 shows an example of frame TR extracted by the MAC sub-layer from a received bit string. Such a frame first comprises a header of 14 octets and formed by three fields:
a destination address of the frame TR;
an address of origin of the frame TR;
a type of data describing the frame TR.

The frame finally comprises useful data transmitted by the source application SAPP and finally error detecting codes CRC.

The data link layer L′₂ on the side of the receiver also comprises a test stage TEST intended to test whether the received frame TR is correct or incorrect. This stage has for its object to detect possible errors which are present in the received frame TR and to realize this it depends on the error detecting codes CRC which have been added to the transmitted data DE by the data link layer L₂ on the side of the transmitter. In practice, polynomial codes are often used, also called cyclic redundancy check codes CRC. In the polynomial codes is considered that the bits of a character string are the coefficients of a polynomial. For example, the string 110001 comprises 6 bits and it represents a polynomial of 6 terms whose coefficients are 1, 1, 0, 0, 0, 1 and are equal to x⁵+x⁴+x⁰. To utilize a polynomial code the transmitter and the receiver are to be in agreement with a choice of the polynomial generator G(x).

To calculate the checksum mentioned earlier of a block of m bits corresponding to a polynomial M(x) and longer than G(x), the principle consists of affixing check bits to the end of the block so that the frame (block and check bits) can be divided by G(x). When the receiver receives a frame, it divides the frame by G(x). If the rest obtained is not zero, there is a transmission error.

In that case the frame is rejected. The link layer L′₂ of the network stack PR₂ of the receiver may request a retransmission of the frame in question to the link layer of the network stack PR₁ of the transmitter.

An example of the method according to the invention is shown in FIG. 4. It is characterized in that it further comprises a frame correction stage COR intended to correct an erroneous frame TE. It is an object of this stage to notably avoid rejecting the erroneous frame and its possible retransmission.

It should be well noted that this frame correction stage COR is situated at the level of the data link layer and that it is applied to received frames called erroneous frames by the test stage TEST. It is at every point different from the data unit correction stage mentioned above, which may be applied to a received data unit at the physical layer by means of error correction codes.

The frame correction stage COR comprises a sub-stage of selecting bits to be corrected BC in the erroneous frame TE from extrinsic data IS of the frame, available at the receiver end. The stage consists of selecting a certain number of bits to be corrected BC in the erroneous frame TE. The bits to be corrected BC are for example those bits that have the greatest probability of being erroneous. Time to correct all the bits of the erroneous frame TE would in effect be prohibitively costly in terms of calculation time. It is thus an object of this sub-stage to limit the number of bits to be corrected and thus the complexity of the method.

The extrinsic data IS of the erroneous frame TE relate, for example, to a priori knowledge of an unequal protection technique of the data (unequal error protection) implemented by the transmitter. Indeed, in this framework certain data present in the erroneous frame have been more protected than others and it may be supposed that the bits forming such data have less probability of being erroneous.

The candidate bits BC are then presented to a candidate frame generation sub-stage GENER intended to form a candidate frame T_{Ca} from candidate bits BC and from the erroneous frame TE. Such a sub-stage depends on pattern generator techniques such as the Chase algorithm or the threshold pattern generator algorithm.

Let us consider an erroneous frame TE to be a bit sequence y=(y₁, y₂, . . . , y_{L}) with L being an integer greater than zero. The principle of the Chase algorithm is the following: let us suppose that the sub-stage of selecting bits to be corrected has selected k bits, with k being an integer greater than zero, as those having the largest probability of being erroneous. The Chase algorithm constructs N patterns in the following way:
one candidate bit is set to 1 and all the others to zero;
2 candidate bits are set to 1 and all the others to zero;
i candidate bits are set to 1 and all the others to zero;
p≦k candidate bits are set to 1 and all the others to zero.
There are thus

$$N = {\sum }_{i = 1}^{p} {C}_{k}^{i}$$

possible patterns.

A pattern Mᵢ is then applied to the erroneous frame TE in the following manner:
Sᵢ=Mᵢ⊕y,
where ⊕ represents the binary OR-exclusive function (XOR). This operation narrows down to inverting in the erroneous frame the candidate bit or candidate bits which has or have been set to 1 in the pattern.

The new obtained frames, also called candidate frames, are then arranged according to a metric which measures a distance to the erroneous frame, the first candidate frame being nearest to the erroneous frame. In the case where an unequal protection of data has been used at the transmitter end, such a distance may be calculated by applying different weights to the inverted bits depending on the protection they have received. The candidate frames arranged such will then be tested according to the set order.

The operation of this algorithm may be influenced by the two parameters k and p. The parameter k determines the maximum number of bits considered faulty in the erroneous frame and the parameter p the number of bits that may be tried to be corrected from the k candidate bits. The parameter p depends on the error correcting codes used and notably their length as well as the transmission as such. It is generally chosen to be less than k/2.

The threshold pattern generator algorithm is at many points similar to the Chase algorithm. It is distinguished by a unique parameter θ instead of k and p. In the candidate bit selection sub-stage all the bits are chosen whose probability of being exact also called trust bits is less than θ. The rest is identical to the Chase algorithm with a minor reservation that p=k, which corresponds to the number of bits below the trust threshold θ.

It should be noted that for the method according to the invention it is only necessary for the frames delivered by the data link layer L₂ to comprise one or various error detecting codes. The frame correction stage according to the invention under no circumstance needs detecting codes which are moreover error correctors. In the presence of error correcting codes the method according to the invention only needs these codes for detecting errors.

The first candidate frame T_{Ca} obtained is then tested by the test stage TEST. If said stage declares it to be correct, the candidate frame T_{Ca} replaces the erroneous frame TE and the correct frame T_{Co} is sent to the upper layer of the network stack PR₂, that is to say, to the network layer L′₃. The data link layer L′₂ can thus transmit a positive acquittal to the destination of the data link layer of the network stack PR₁ of the transmitter.

If, on the other hand, the first candidate frame T_{Ca} is declared erroneous by the test stage TEST, the second candidate frame is tested in its turn. In a first embodiment of the invention such a process is repeated until all the generated candidate frames are tested or one frame is declared correct. If no candidate frame is satisfactory, the data link layer L₂ sends a negative settlement to the transmitter by asking for a possible retransmission of the erroneous frame.

With the Chase algorithm we have seen that it was possible to define the number of bits to be corrected by the parameters p and k and thus to choose a desired number of candidate frames T_{Ca}. The number of repetitions is thus known in advance and does not vary as a function of the received frames. On the other hand, the threshold pattern generation algorithm operates differently. It utilizes a trust threshold θ as the bits to be corrected have a probability of being exact lower than this threshold. The number of bits to be corrected thus varies with the received frames, for example, as a function of transmission conditions. Thus it could happen that the number of candidate frames generated by such an algorithm is very high because many bits have a probability of being exact that is lower than the threshold θ, which would render the cost of correction prohibitive. This is the reason why in a second embodiment of the invention the error frame correction stage COR further comprises a check sub-stage CONT intended to count a number of candidate frames and stop the test of candidate frames if said number reaches a predetermined threshold. An advantage of this second embodiment is that the number of repetitions of said correction stage COR is limited and not the processing time of received frames is increased too much.

It should be noted that also a minimum threshold could be introduced to guarantee a minimum number of candidate frames.

The check sub-stage CONT is shown in FIG. 5. It comprises a counting function COUNT intended to count the number nb of candidate frames already tested and a comparing function STOP of comparing this number nb to a threshold, intended to stop the correction process if the number nb is higher than the predetermined threshold nbmax. In this case it is suitable to adapt the choice of (k,p) or of θ to nbmax so as to avoid generating useless frames in the candidate flame generation sub-stage GENER.

In what has been stated above, no hypothesis has been made as to an important stage of the physical layer L′₁, which is the channel decoding CDEC. The object of such a stage is to convert a transported data unit in the form of a physical signal by the transmission channel C into digital data also called bit string. The physical signal received by the receiver comprises real values that the channel decoding stage CDEC is to convert into bits. There are mainly two types of channel decoding algorithms: the simpler one associates a binary value equal to 0 or 1 to a real value of the physical signal, also called binary decision. Such an algorithm is called “hard” at the output. The second associates to said real value not only a binary value but also a trust measure which expresses the probability that the decision is exact. This second algorithm is called “soft” algorithm at the output. In this second case the channel decoder delivers not only a string of hard bits but also a string of soft bits comprising quantized values of trust measures.

The method according to the invention as described previously relates to a hard frame TD delivered by the transformation stage R_TRANS of the data link layer L₂ from a hard bit string TBD coming from the physical layer L₁. Said hard bit string TBD is formed by decisions made by the channel decoding stage CDEC of the physical layer L₁. Only the “hard” outputs of the channel decoding stage CDEC are thus used by the transformation stage R_TRANS.

In the preferred embodiment of the invention shown in FIG. 6 this time a soft output channel decoding stage is considered. The object is to utilize the trust measures associated with the decisions delivered by the channel decoding stage for the correction of an error frame. More exactly, said trust measures are intended to be taken into account by the selection sub-stage SEL of bits to be corrected for the choice of bits that have the greatest probability of being erroneous.

Let us consider a real physical signal received by the physical layer L₁ comprising L real values, with L being a non-zero integer. Let us suppose that the channel decoding stage at the “soft” output has delivered a binary decision hᵢ and a trust measure cᵢ for a real value i of said physical signal, where i is situated between 1 and L. In order to be transmitted from the physical layer L₁ to the data link layer L₂, said trust measure cᵢ is to be quantized by a quantization sub-stage of the channel decoding stage CDEC₂, according to a technique known to the expert and intended to deliver N−1 bits (s_{i,2}, . . . , s_{i,N}) with N being an integer greater than or equal to 1. As is shown in FIG. 7, a real value i of a physical signal received by the channel decoding stage CDEC₂ is thus represented by N bits, N≧1 (s_{i,1}, s_{i,2}, . . . , s_{i,N-1}). Said quantization sub-stage thus delivers a string of hard bits TBD and a string of soft bits TBS, said soft bit string being constructed by concatenating binary representations of the L real values over N−1 bits.

Said soft bit string TBS is shown in FIG. 7. The most significant soft bits (s_{i,1}, s_{2,2}, . . . , s_{2,L}) are placed first, then the less significant soft bits and so on up to the least significant soft bits (s_{N,1}, s_{N,2}, . . . , s_{N,L}).

It should be noted that the soft bit string TBS is then transmitted without any difficulty from the physical layer L₁ to the data link layer L₂. The physical layer and the data link layer are indeed often combined to a single layer and the exchange of data between them is facilitated because of this.

The hard bit string TB and the soft bit string TBS are then received by the transformation stage R_TRANS. The not very restrictive hypothesis is made that said transformation stage knows the number of bits N utilized for the quantization. Also knowing the length of the bit string TBS the transformation stage is then capable of dividing said bit string into N−1 sections of equal size Tₙ, n being situated between 1 and N−1. From the section Tₙ it thus constructs a soft frame TSₙ. From the hard bit string TBD it constructs a hard frame TD.

The hard frame TD is then transmitted to the test stage TEST. If said hard frame TD is declared correct, it is sent to the network layer L′₃ and a positive settlement is sent to the transmitter. If, on the other hand, said hard frame is declared erroneous, it is transmitted to the frame correction stage COR.

The erroneous bard frame TE is received by the selection sub-stage SEL for bits to be corrected, as are the N−1 soft frames Tsₙ which are associated thereto. These N−1 soft frames constitute the extrinsic data IS intended to be used by the sub-stage SEL for selecting bits to be corrected. In a simple way the sub-stage SEL for selecting bits to be corrected may find back the trust measures contained in the N−1 soft frames Ts₁ and use these trust measures for selecting the bits of the hard frame that have the largest probability of being erroneous, for example, with the aid of one of the two algorithms that have been shown above.

As has been seen previously, the bits to be corrected BC are transmitted to the sub-stage GENER of generating a candidate frame. This sub-stage may also advantageously utilize the trust measures delivered by the channel decoding stage at the “soft” output, to put the candidate frames in the order from the most probable to the least probable. For example, it may be considered that a candidate frame where only the bit that has the greatest probability of being erroneous has been modified, is nearer to the sought frame than a candidate frame obtained from modifying a bit that has less probability of being erroneous.

The advantage of the latter embodiment is that additional data, the soft data available at the level of the physical layer L′₁, can be benefited from to better correct the erroneous frames of the data link layer L′₂.

The invention is not restricted to the embodiments that have just been described by way of example. Modifications or improvements may be applied while remaining within the scope of the invention.

The description above with reference to FIGS. 1 to 7 illustrates the invention rather than limits same. It is evident that there are other alternatives that remain within the framework of the appended claims.

There are many ways of implementing the functions described by means of software. With respect thereto FIGS. 1 to 7 are very diagrammatic, each Figure representing only one embodiment. Thus, although a Figure shows various functions in the form of separate blocks, this does not exclude that a single software item carries out various functions. This does not exclude either that one function can be carried out by a software set.

It is possible to implement these functions by means of a receiver circuit comprising one or various processors, said processors being suitably programmed. A set of instructions contained in a program memory may cause the circuit to carry out various operations described earlier with reference to FIGS. 1 to 7. The set of instructions may also be loaded in the program memory by reading a data carrier, for example, a CD-ROM. Reading may also effected via a communication network such as the Internet network. In that case a service provider will put a set of instructions at the disposal of interested parties.

No reference sign in brackets in a claim is to be interpreted in limitative fashion. The verb “to comprise” does not exclude the presence of other elements or stages and those listed in a claim. The word “a” or “an” preceding an element or a stage does not exclude the presence of a plurality of these elements or stages.

1. A processing method for a data unit received by a receiver via a network, the method comprising a channel decoding stage (CDEC₁, CDEC₂) of the received data unit (UDR), intended to deliver at least a string of hard bits (TBD), a transformation stage (R_TRANS) of said hard bit string (TBD) into a hard frame (TD), said hard frame comprising at least an error detecting code and a test stage (TEST) intended to test on the basis of said error detecting code whether said hard frame (TD) is correct or incorrect, said method further comprising a frame correction stage (COR) intended to correct an incorrect frame (TE) into a correct frame (T_{co}), said stage comprising:
a sub-stage (SEL) of selecting bits to be corrected (BC) in an incorrect frame (TE), from data (IS) extrinsic to said incorrect frame;
a sub-stage (GENER) of generating a candidate frame (T_{ca}) from bits to be corrected (BC) and the incorrect frame (TE), said candidate frame being intended to be tested by the test stage (TEST).

2. A processing method as claimed in claim 1 of a data unit received by a receiver, characterized in that said channel decoding stage (CDEC₂) of the received data unit (UDR) is intended to deliver a soft bit string (TBS) and in that said transformation stage (R_TRANS) is intended to transform said soft bit string (TBS) into at least a soft frame (TSₙ), said soft frame (TSₙ) being intended to be used as extrinsic data (IS) of the incorrect frame (TE).

3. A processing method as claimed in claim 1 of a data unit (UDR) received by a receiver, said frame correction stage (COR) being repeated as long as the candidate frame generation sub-stage (GENER) delivers a new candidate frame (T_{Ca}) and the new candidate frame (T_{Ca}) is declared erroneous by said test stage (TEST).

4. A processing method as claimed in claim 3 of a data unit (UDR) received by a receiver, further comprising a check sub-stage (CONT) intended to count a number of candidate frames (nb) and to stop the frame correction stage (COR) if said number reaches a predetermined threshold (nb_max).

5. A receiver intended to process a received data unit (UDR), comprising channel decoding means (CDEC₁, CDEC₂) of the received data unit (UDR), intended to deliver at least a hard bit string (TBD), transformation means (R_TRANS) for transforming said hard bit string (TBD) into a hard frame (TD), said hard frame comprising at least an error detecting code, and test means (TEST) intended to test on the basis of said error detecting code whether said hard frame (TD) is correct or incorrect, said receiver further comprising frame correction means (COR) intended to correct an incorrect frame (TE) into a correct frame (T_{Co}), said means comprising:
means (SEL) for selecting bits to be corrected in the incorrect frame (TE) based on data (IS) extrinsic to the frame;
generation means (GENER) for generating a candidate frame (T_{Ca}) based on bits to be corrected (BC) and on the incorrect frame (TE), said candidate frame (T_{Ca}) being intended to be tested by the test stage (TEST).

6. A receiver as claimed in claim 5, characterized in that said channel decoder (CDEC₂) is intended to deliver a soft bit string (TBS) and in that said transformation means (R_TRANS) are intended to transform said soft bit string (TBS) into at least one soft frame (TSₙ), said soft frame (TSₙ) being intended to be used as extrinsic data (IS) to the incorrect frame (TE).

7. A transmission system comprising a transmitter intended to transmit a data unit via a network and a receiver intended to process a received data unit (UDR), said receiver comprising channel decoding means (CDEC₁, CDEC₂), of the received data unit intended to deliver at least a hard bit string (TBD), transformation means (R_TRANS) for transforming said hard bit string (TBD) into a hard frame (TD), said hard frame comprising at least an error detecting code and test means (TEST) intended to test on the basis of said error detecting code whether said hard frame (TD) is correct or incorrect, said receiver further comprising frame correction means (COR), intended to correct an incorrect frame (TE) into a correct frame (T_{Co}), said means comprising:
means (SEL) for selecting bits to be corrected in the incorrect frame (TE) based on data (IS) extrinsic to the frame;
generation means (GENER) for generating a candidate frame (T_{Ca}) based on bits to be corrected (BC) and on the incorrect frame (TE), said candidate frame (T_{Ca}) being intended to be tested by the test stage (TEST).

8. A transmission system as claimed in claim 7, characterized in that said channel decoder (CDEC₂) is intended to deliver a soft bit string (TBS) and in that said transformation means (R_TRANS) are intended to transform said soft bit string (TBS) into at least a soft frame (TSₙ), said soft frame (TSₙ) being intended to be used as extrinsic data (IS) to the incorrect frame (TE).

9. A computer program for a receiver comprising a set of instructions for implementing a method as claimed in claim 1 when said program is executed by a processor.

10. A signal intended to convey a computer program as claimed in claim 9.
